(19) United States
(12) Patent Application Publication
(10) Pub. No.: US 2026/0180549 A1
(43) Pub. Date: Jun. 25, 2026

(54) SURFACE ACOUSTIC WAVE (SAW) RESONATORS WITH INTERDIGITATED TRANSDUCER (IDT) FINGERS HAVING TRAPEZOIDAL SHAPED PORTIONS AND CONSTANT FINGER SEPARATION AND RELATED METHODS

(71) Applicant: RF360 Singapore Pte. Ltd., Singapore (SG)

(72) Inventors: Chee Ming Adrian Ma, Singapore (SG); Wee Chuan Tay, Singapore (SG); Kin Wah Tong, Singapore (SG); Kok Meng Ee, Singapore (SG); Dan Wang, Singapore (SG)

(21) Appl. No.: 18/989,534

(22) Filed: Dec. 20, 2024

(51) Int. Cl. H03H 9/145; H03H 3/08; H03H 9/25

(52) U.S. Cl. CPC H03H 9/14558; H03H 3/08; H03H 9/25

(57) ABSTRACT

To reduce the effect of ripple caused by reflected waves in a piezoelectric layer, a surface acoustic wave (SAW) resonator employs interdigitated transducer (IDT) fingers that vary in width while maintaining constant finger pitch to shift the frequency response and smooth the ripple in the output signal. A change in width along the IDT finger corresponds to a change in the metallization ratio or loading on the surface of the piezoelectric layer. As the width of the IDT finger changes relative to a default width, the range of the metallization ratio along the finger provides a range of frequency response, including the ripple. The IDT finger has a trapezoidal shape changing width along the length of the finger. The range of the frequency response generated in this manner causes the output signal to be a blend of the range of frequency responses in which the ripple is smoothed.

### TECHNICAL FIELD

The technology of the disclosure relates generally to wireless transceivers and other components that employ microacoustic filters and, more specifically, to microacoustic filters employing surface acoustic wave (SAW) resonators.

### BACKGROUND

Electronic devices may use radio-frequency (RF) signals to communicate information that enables voice communication, uploading and downloading of media (e.g., audio and video), remote control of household devices, and reception of global positioning information, for example. To transmit or receive the radio-frequency signals within a given frequency band allocated for such communications, the electronic device may use filters that pass signals within the frequency band and suppress (e.g., attenuate) jammers or noise-having frequencies outside of the frequency band. It can be challenging, however, to design and manufacture a filter that provides filtering for radio-frequency applications.

### SUMMARY

Aspects disclosed in the detailed description include surface acoustic wave (SAW) resonators with interdigitated transducer (IDT) fingers having trapezoidal-shaped portions and constant finger separation. Related methods of manufacturing a SAW filter with IDT fingers having trapezoidal-shaped portions and constant finger separation are also disclosed. Surface acoustic waves that propagate through a piezoelectric layer can reflect off of the side and bottom surfaces of the piezoelectric layer and back to the surface. Waves reflected back at high angles (e.g., forty (40) degrees or higher) to the surface can be a major source of ripple in the output of a SAW filter. To reduce the effect of such ripple, an exemplary SAW resonator employs IDT fingers that vary in width over the finger length while maintaining constant finger pitch to shift the frequency response and smooth the ripple in the output signal. A change in width along a portion of the IDT finger corresponds to a change in the metallization ratio or loading on the surface of the piezoelectric layer. As the width of the IDT finger changes relative to a default width, the range of the metallization ratio along the finger provides a range of frequency response, including the ripple. In some examples, the IDT finger has a trapezoidal shape changing width along the length of the finger. In some examples, there may be multiple trapezoidal portions. The range of the frequency response generated in this manner causes the output signal to be a blend of the range of frequency responses in which the ripple is smoothed (e.g., reduced in magnitude) in the output signal.

In this regard, in one aspect, a SAW resonator is disclosed. The SAW resonator includes a piezoelectric layer including a first surface having a first area extending in a first direction and a second direction orthogonal to the first direction, and an IDT structure on the first surface in the first area, the IDT structure including first electrode fingers alternating with second electrode fingers in the first direction. Each of the first electrode fingers in the SAW resonator includes a first portion having a first trapezoidal shape, and a width of the first portion in the first direction decreases in the second direction. Each of the second electrode fingers in the SAW resonator includes a second portion having the trapezoidal shape, and a width of the second portion in the first direction increases in the second direction. A first distance, in the first direction, between a first electrode finger of the first electrode fingers and a second electrode finger of the second electrode fingers is constant in the second direction.

In another aspect, a microacoustic filter including a plurality of SAW resonators is disclosed. Each of the SAW resonators includes a piezoelectric layer including a first surface having a first area extending in a first direction and a second direction orthogonal to the first direction, and an interdigitated transducer (IDT) structure on the first surface in the first area, the IDT structure including first electrode fingers alternating with second electrode fingers in the first direction. Each of the first electrode fingers of the SAW resonators includes a first portion having a first trapezoidal shape, and a width of the first portion in the first direction decreases in the second direction. Each of the second electrode fingers of the SAW resonators includes a second portion having the trapezoidal shape, and a width of the second portion in the first direction increases in the second direction. A first distance, in the first direction, between a first electrode finger of the first electrode fingers and a second electrode finger of the second electrode fingers is constant in the second direction.

In another aspect, a method of manufacturing a SAW resonator is disclosed. The method includes forming a piezoelectric layer including a first surface having a first area extending in a first direction and a second direction orthogonal to the first direction and forming an interdigitated transducer (IDT) structure on the first surface in the first area, the IDT structure including first electrode fingers alternating with second electrode fingers in the first direction. Each of the first electrode fingers of the SAW resonator includes a first portion having a first trapezoidal shape, and a width of the first portion in the first direction decreases in the second direction. Each of the second electrode fingers of the SAW resonator includes a second portion having the trapezoidal shape, and a width of the second portion in the first direction increases in the second direction. A first distance, in the first direction, between a first electrode finger of the first electrode fingers and a second electrode finger of the second electrode fingers is constant in the second direction

### BRIEF DESCRIPTION OF THE DRAWINGS

FIG. 1 illustrates an example operating environment for operating a surface acoustic wave (SAW) resonator in which fingers of the interdigitated transducer (IDT) include portions having trapezoidal shapes and constant finger separation distance to smooth ripple in an output signal;

FIG. 2 illustrates an example wireless transceiver including at least one microacoustic filter, including SAW resonators in which IDT fingers include trapezoidal shapes and constant finger separation distance to smooth ripple in an output signal;

FIG. 3 is an illustration of a perspective view of a SAW resonator to illustrate examples of reflected acoustic waves that may cause ripple in the frequency response of the SAW resonator;

FIG. 4 is a plan view of a first example of an IDT in which the fingers each have a trapezoidal shape to provide a range of metallization ratio affecting the frequency response to smooth the ripple caused by reflected acoustic waves;

FIGS. 5A and 5B are illustrations of an IDT corresponding to FIG. 4 in which the fingers have a trapezoidal shape and examples of frequency responses at intervals along the length of the fingers in a SAW resonator to illustrate the blended output signal generated using the IDT;

FIG. 6 is a flowchart of a method of making the SAW resonators in FIG. 4, including IDT fingers having trapezoidal-shaped portions and constant finger separation distance;

FIG. 7 is a plan view of a second example of an IDT in which the fingers each include two trapezoidal-shaped portions and constant finger separation to provide frequency response ranges that smooth out the effect of ripple in the output signal;

FIG. 8 is a plan view of a third example of an IDT in which the fingers each include multiple trapezoidal-shaped portions and constant finger separation to provide frequency response ranges that smooth out the effect of ripple in the output signal;

FIG. 9 is a block diagram of an exemplary wireless communication device that includes microacoustic filters, including SAW resonators in which IDT fingers include trapezoidal shaped portions and constant finger separation distance to smooth ripple caused by reflected waves;

FIG. 10 is a block diagram of an exemplary processor-based system that can include microacoustic filters including SAW resonators in which IDT fingers include trapezoidal-shaped portions and constant finger separation distance to smooth ripple caused by reflected waves;

FIGS. 11A and 11B are an example of a thin-film (TF) SAW (TF-SAW) stack that may employ the IDTs in FIGS. 4, 5A, 7, and 8; and

FIGS. 12A and 12B are an example of a temperature-compensated (TC) SAW (TC-SAW) stack that may employ the IDTs in FIGS. 4, 5A, 7, and 8.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include surface acoustic wave (SAW) resonators with interdigitated transducer (IDT) fingers having trapezoidal shaped portions and constant finger separation. Related methods of manufacturing an SAW filter with IDT fingers that have trapezoidal-shaped portions and constant finger separation are also disclosed. Surface acoustic waves that propagate through a piezoelectric layer can reflect off of the side and bottom surfaces of the piezoelectric layer and back to the surface. Waves reflected back at high angles (e.g., forty (40) degrees or higher) to the surface can be a major source of ripple in the output of a SAW filter. To reduce the effect of such ripple, an exemplary SAW resonator employs IDT fingers that vary in width over the finger length while maintaining constant finger pitch to shift the frequency response and smooth the ripple in the output signal. A change in width along a portion of the IDT finger corresponds to a change in the metallization ratio or loading on the surface of the piezoelectric layer. As the width of the IDT finger changes relative to a default width, the range of the metallization ratio along the finger provides a range of frequency response, including the ripple. In some examples, the IDT finger has a trapezoidal shape changing width along the length of the finger. In some examples, there may be multiple trapezoidal portions. The range of the frequency response generated in this manner causes the output signal to be a blend of the range of frequency responses in which the ripple is smoothed (e.g., reduced in magnitude) in the output signal.

To transmit or receive radio-frequency signals within a given frequency band, an electronic device may use filters to pass signals within the frequency band and to suppress (e.g., attenuate) jammers or noise-having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). In an acoustic resonator or an acoustic filter, an electrical signal having a frequency-varying signal is applied to an electrode structure to create an electric field of varying intensity in a piezoelectric material. The piezoelectric material transforms the varying electric field into acoustic waves. The resonant frequencies of acoustic resonators are determined by the dimensions of the acoustic resonator and/or electrode structure. The filtered acoustic waves induce an electric field in the piezoelectric material, and the electrode structure detects the electric field as voltage and transforms or converts it to an electrical output signal.

It can be challenging to design a filter that is affordable and can realize a target level of performance in terms of resonance quality factors, electromechanical coupling, power durability, insertion loss, and spurious-mode suppression.

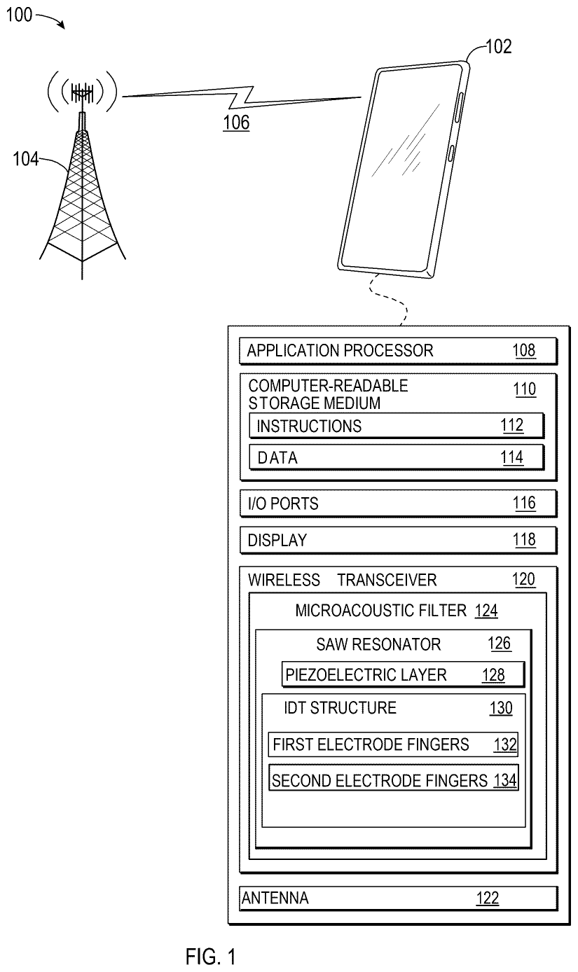

FIG. 1 illustrates an example environment 100 for operating an SAW resonator with IDT fingers with trapezoidal-shaped portions and a constant spacing between fingers to smooth the ripple caused by reflected waves. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth. Use of a microacoustic filter is not limited to wireless communication as a microacoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th-generation (6G) cellular; IEEE 802.11 (e.g., Wi-Fi®); IEEE 802.15 (e.g., Bluetooth®); IEEE 802.16 (e.g., WiMAX200); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102 and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one microacoustic filter 124 including at least one SAW resonator 126. In some devices, the microacoustic filter 124 includes multiple SAW resonators 126, which can be arranged in series, in parallel, in a ladder structure, in a lattice structure, in some combination thereof, or another configuration. The SAW resonator 126 includes a piezoelectric layer 128 with an IDT structure 130 on a surface of the piezoelectric layer 128. The IDT structure 130 may include first electrode fingers 132 and second electrode fingers 134 extending across the surface of the piezoelectric layer 128. The first electrode fingers 132, also referred to herein as first type fingers 132, and the second electrode fingers 134, also referred to herein as second type fingers 134, are disposed in an alternating order in a direction orthogonal to the electrode fingers 132, 134. The first type fingers 132 decrease in width in a first direction along the length of the fingers while the second type fingers 134 increase in width. In this manner, a constant spacing between the first type fingers 132 and the second type fingers 134 is maintained along the fingers 132, 134. The IDT structure 130 reduces the magnitude of ripple in the SAW resonator 126 due to waves reflected from the sides and bottom of the piezoelectric layer 128.

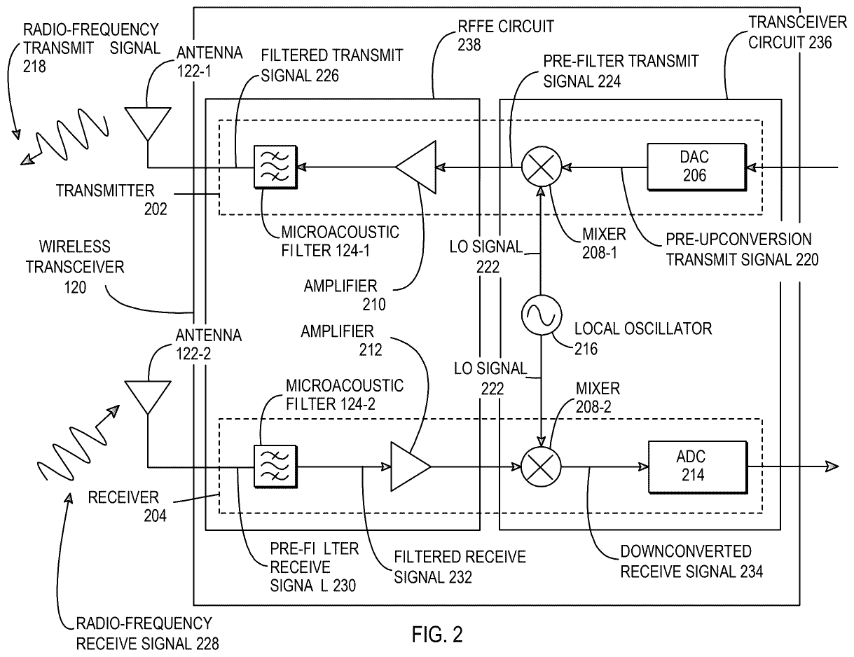

With these improvements, the microacoustic filter 124 can be designed to support frequency ranges above 300 MHz and, in particular, at Cellular wireless spectrum frequencies. The microacoustic filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the DAC 206 of the transmitter 202 and the ADC 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the DAC 206 of the transmitter 202, the mixer 208-1 of the transmitter 202, the mixer 208-2 of the receiver 204, and the ADC 214 of the receiver 204. In other implementations, the DAC 206 and the ADC 214 can be implemented on another separate circuit that includes the application processor 108 or the modem. The RFFE circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the DAC 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second microacoustic filter 124-2 accepts the received radio-frequency receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The ADC 214 converts the downconverted receive signal 234 into a digital signal, which can be processed by the application processor 108 or another processor associated with the wireless transceiver 120 (e.g., the modem).

FIG. 2 illustrates one example configuration of the wireless transceiver 120. Other configurations of the wireless transceiver 120 can support multiple frequency bands and share an antenna 122-1 or 122-2 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120.

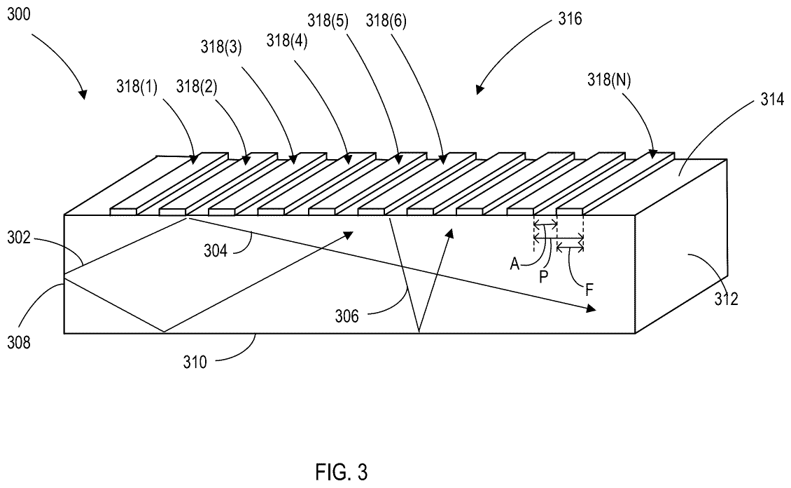

FIG. 3 is a perspective view of a SAW resonator 300 provided to illustrate examples of acoustic waves 302, 304, and 306 that may be reflected from side surfaces 308 and/or a bottom surface 310 of a piezoelectric layer 312 and return to a top surface 314 to be detected by an IDT 316 as a ripple in the frequency response of the SAW resonator 300. A frequency-varying signal may be applied to the IDT 316 to create surface waves (not shown) that propagate along the top surface 314 in the X-axis direction in FIG. 3. However, those surface waves may also propagate from the top surface 314 at various angles to bounce off the side surfaces 308 and the bottom surface 310 or the waves may propagate directly to the bottom surface 310 before returning back to the top surface 314.

The frequency-varying signal may be applied to fingers 318(1)-318(N) of the IDT 316 as a first voltage applied to the oddly numbered fingers (e.g., 318(1), 318(3), 318(5), etc.) and a second voltage applied to the evenly numbered fingers (318(2), 318(4), 318(6), etc.). In response to the time-varying voltage, the piezoelectric layer 312 may generate the surface acoustic waves in the X-axis direction, orthogonal to the IDT fingers 318(1)-318(N).

The frequency response of the SAW resonator 300 detected at the fingers 318(1)-318(N) depends, at least in part, on the width F of the fingers 318(1)-318(N) and the separation distance A between the fingers 318(1)-318(N). The width F and the separation distance A determine a pitch P (e.g., edge to edge distance) of the fingers 318(1)-318(N) as well as a metallization ratio of the top surface 314. The pitch P may be used to control a resonant frequency of the SAW resonator 300. The metallization ratio is a ratio of an area of the top surface 314 covered by metal and an area not covered by metal. Since the fingers 318(1)-318(N) extend across the entire piezoelectric layer 312 in this example, the metallization ratio can be determined as a ratio of the width F to the pitch P. The metallization ratio affects the speed at which the acoustic waves propagate across the top surface 314. The presence of the metal of the fingers 318(1)-318(N) on the top surface 314 tends to slow the rate at which acoustic waves propagate through the piezoelectric layer 312. Thus, waves on the top surface 314 travel faster when the metallization ratio is lower, which also affects the frequency response of the SAW resonator 300.

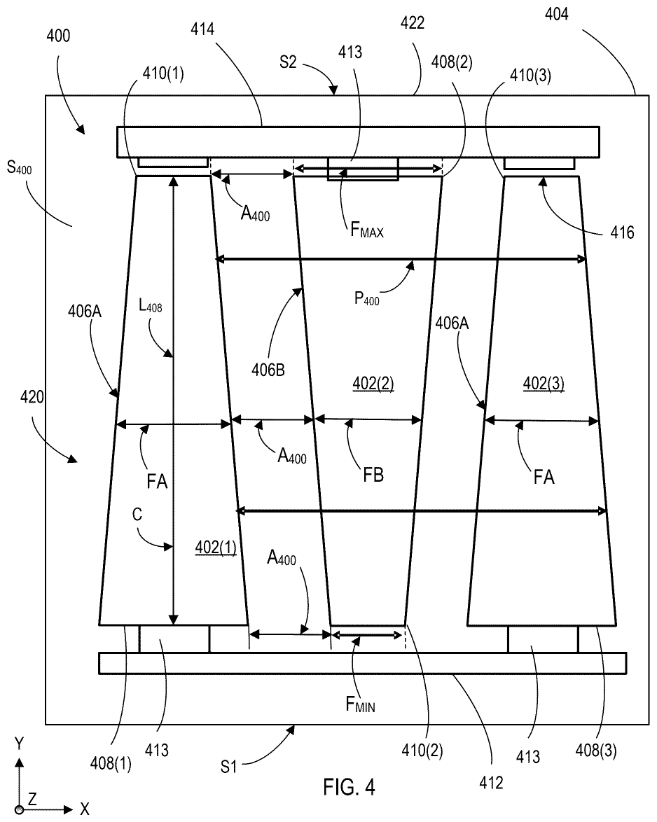

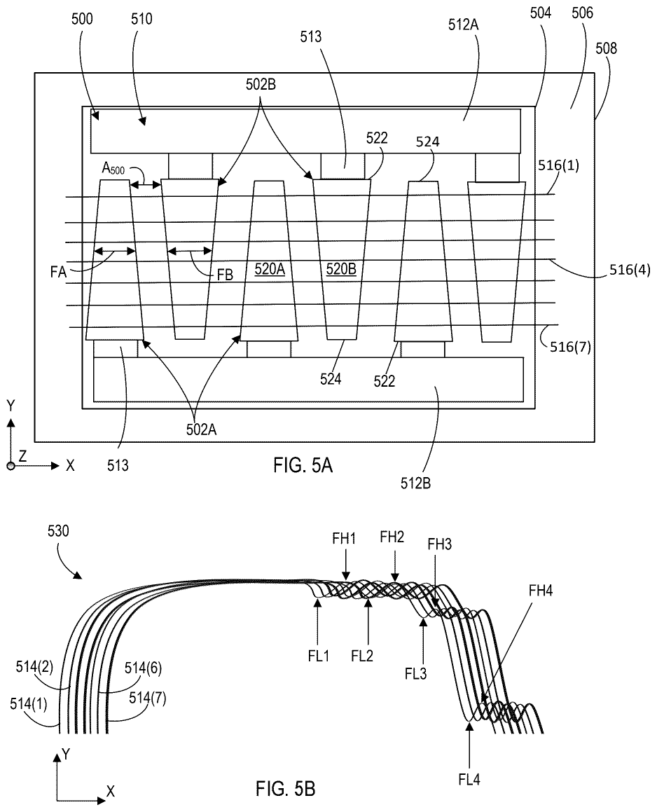

FIG. 4 is an example of an IDT 400 in which fingers 402(1)-402(3) each have trapezoidal shaped portions that provide a range of metallization ratios affecting the frequency response of a SAW resonator 404 to smooth the ripple caused by reflected acoustic waves. The IDT 400 may include additional fingers (not shown) corresponding to the fingers 402(1)-402(3), as shown in FIG. 5A. The fingers 402(1)-402(3) include fingers 402(1) and 402(3) that are a first electrode finger 406A and finger 402(2) is a second electrode finger 406B. Thus, the IDT 400 includes the first electrode fingers 406A alternating with the second electrode fingers 406B in a first, X-axis direction.

The fingers 402(1)-402(3) include first ends 408(1)-408(3) having a maximum width F_{MAX}(in the X-axis direction) and second ends 410(1)-410(3) having a minimum width F_{MIN}. In the example in FIG. 4, the fingers 402(1)-402(3) include trapezoid shaped portions extending from the first ends 408(1)-408(3) to the second ends 410(1)-410(3). In some examples, the minimum width F_{MIN} is in a range of eighty-nine percent (89%) to ninety-five percent (95%) of the maximum width F_{MAX} but may be in a range of eighty percent (80%) to ninety-eight percent (98%) of the maximum width F_{MAX}. The IDT 400 is disposed in a surface area 420 on a surface S₄₀₀ of a piezoelectric layer 422 that extends in a first, X-axis direction and a second, Y-axis direction. The IDT 400 includes a first interconnect 412 (e.g., busbar) that extends in the first, X-axis direction on a first side S1 of the surface area 420 and couples to the first ends 408(1) and 408(3) of the first electrode fingers 406A. The IDT 400 includes a second interconnect 414 (e.g., busbar) that extends in the first, X-axis direction on a second side S2 of the surface area 420 and couples to the first end 408(2) of the second electrode finger 406B. The fingers 402(1)-402(3) also have second ends 410(1)-410(3), which are opposite to the first ends 408(1)-408(3). The first electrode fingers 406A are also referred to herein as first type fingers 406A, and the second electrode fingers 406B may be referred to herein as second type fingers 406B.

The IDT 400 includes segments 413 to couple the first ends 408(1) and 408(3) to the first interconnect 412 and couple the first end 408(2) to the second interconnect 414. The segments 413 in this example are narrower in width, in the first, X-axis direction, than the maximum width F_{MAX} but, in other examples, may be the maximum width F_{MAX}. Alternatively, the first ends 408(1)-408(3) may couple directly to the first and second interconnects 412 and 414 without the segments 413.

Each of the first type fingers 406A and the second type fingers 406B have a trapezoidal shape, such that the width FA of the first type fingers 406A in a first, X-axis direction decreases in a second, Y-axis direction and the width FB of the second type fingers 406B increases in the second, Y-axis direction. Thus, a separation distance A₄₀₀ may remain constant along the length of the fingers 402(1)-402(3) (or constant within some manufacturing tolerance amount). The second ends 410(1)-410(3) each have a linear edge 416 extending in the first, X-axis direction. The separation distance A₄₀₀ in the first direction between a first type finger 406A and a second type finger 406B may be in a range of 19% to 250% of an average width in the first direction of the first portion of each of the first type fingers 406A. In some examples, the second type finger 406B may be in a range of 31% to 210% of an average width in the first direction of the first portion of each of the first type fingers 406A. An average width of the first type fingers 406A may be determined as an average of the minimum width F_{MIN} and the maximum width F_{MAX.} In some examples, a length L₄₀₈ of the fingers 402(1)-402(3) in the second, Y-axis direction is more than double (e.g., two times) the maximum width F_{MAX}. In some examples, the second ends 410(1)-410(3) having the minimum width F_{MIN} may be coupled to the first and second interconnects 412, 414.

Because the first type fingers 406A and the second type finger 406B have a same trapezoidal shape that is symmetric with respect to a center axis, such as the center axis C of the finger 402(1), and oriented to oppose each other, the separation distance A₄₀₀ between the second type finger 406B and the first type fingers 406A remains constant in the second, Y-axis direction. That is, the separation distance A₄₀₀ between the first end 408(1) of the first type finger 406A and the second end 410(2) of the second type finger 406B is equal to the distance A₄₀₀ between the second end 410(1) of the first type finger 406A and the first end 408(2) of the second type finger 406B. In addition, the pitch P₄₀₀ of the fingers 402(1)-402(3) remains constant in the second, Y-axis direction.

As the width FA of the finger 402(1) changes in the second, Y-axis direction while the separation distance A remains constant, the metallization ratio also changes along the length of the finger 402(1). The range of the width FA from the maximum width F_{MAX} at the first end 408(1) to the minimum width F_{MIN} at the second end 410(1) provides a range in the metallization ratio. Midway between the first end 408(1) and the second end 410(1) of the finger 402(1), where the width FA is midway between the minimum width F_{MIN} and the maximum width F_{MAX}, the metallization ratio may be an average metallization ratio over the length of the finger 402(1). Accordingly, the speed of propagation of the acoustic waves varies along the length of the finger 402(1), the timing of signals received in the finger 402(1) varies over the length of the finger 402(1), and the frequency response varies along the finger 402(1). For example, the first end 408(1) of the finger 402(1) may detect a reflected wave at a different frequency at the same time than the second end 410(1), such that the ripple in an output signal caused by a reflected wave received in the finger 402(1) may be spread out over time. In this regard, the detection of reflected waves may shift according to frequency over the length of the finger 402(1). Accordingly, ripples in the output signal may be smoothed out, as described further with reference to FIGS. 5A and 5B.

The metallization ratio may be defined as a ratio of the total area of the first type fingers 406A and the second type fingers 406B in the IDT 400 to a surface area of the piezoelectric layer over which the IDT 400 is disposed. In the SAW resonator 404, a ratio of the total area of the first type fingers 406A and the second type fingers 406B in the first and second directions to the surface area 420 of the piezoelectric layer 422 may be in a range of 30 percent (30%) to eighty percent (80%).

FIG. 5A is an illustration of an IDT 500 in which first electrode fingers 502A and second electrode fingers 502B have trapezoidal shaped portions corresponding to the fingers 402(1)-402(3) in FIG. 4. The IDT 500 is disposed in a first area 504 on a first surface 506 of a piezoelectric layer 508 extending in a first, X-axis direction and a second, Y-axis direction in a SAW resonator 510 (where the X and Y axes are orthogonal to each other). The first electrode fingers 502A and the second electrode fingers 502B are separated a first distance A₅₀₀ in the first direction. Each of the first electrode fingers 502A are coupled to an interconnect 512A and each of the second electrode fingers 502B are coupled to an interconnect 512B.

The first type fingers 502A and the second type fingers 502B include trapezoidal shaped portions 520A, 520B, respectively, extending in opposite directions from a first end 522 to a second end 524. Thus, the first electrode fingers 502A are also referred to herein as first type fingers 502A, and the second electrode fingers 502B are also referred to herein as second type fingers 502B.

The first type fingers 502A may be directly coupled to the interconnect 512A, or the first ends 522 may be coupled to the interconnect 512A by segments 513, as shown in FIG. 5A. Similarly, the second type fingers 502B may be directly coupled to the interconnect 512B, or the first ends 522 may be coupled to the interconnect 512B by segments 513, as shown in FIG. 5A. In some examples, the segments 513 may be the same width or narrower in the X-axis direction than the first ends 522.

As described with reference to FIG. 4, an effect of a reflected wave received at the first type fingers 502A and the second type fingers 502B may gradually shift in frequency response and/or time with the changes in width FA and FB. In this manner, the effect of reflected waves (e.g., ripple) detected at locations 516(1)-516(7) in the fingers 502 may be smoothed in an output electrical signal. In this context, the term “smoothed” refers to spreading out the effect of the ripple to reduce the magnitude of the ripple (e.g., voltage variation) at a particular frequency. Since the frequency response may gradually change over the length of the fingers 502A, 502B, the electrical signal received by the interconnects 512A and 512B may include a range of frequency responses at a given point in time, as shown in FIG. 5B.

FIG. 5B is a graph 530 of frequency responses 514(1)-514(7) at the locations 516(1)-516(7) along the fingers 502A, 502B in FIG. 5A due to the change in widths FA and FB. The graph 530 shows magnitudes in the Y-axis direction and frequencies in the X-axis direction. In this example, the ripple in the received signal in the frequency response 514(1) is shown as low points in magnitude occurring at frequencies FL1 to FL4 and corresponding peaks in frequency response 514(1) occurring at frequencies FH1, FH2, FH3, and FH4. Each of the frequency responses 514(2)-514(7) include the same low points and peaks as the frequency response 514(1) shifted in frequency. The interconnect 512A receives an electrical signal that is a combination of the respective frequency responses 514(1)-514(7) combined into a single output signal. The detection of a reflected wave at a particular frequency is shifted to other frequencies, which may increase the range of frequencies affected by the ripple, but the magnitude of the ripple at and around the particular frequency of the reflected wave may be significantly reduced in the output signal. In this regard, the trapezoidal shaped fingers 502A, 502B provide a smoother frequency response than would be generated by an IDT having constant width fingers, such as the fingers 318(1)-318(N) in FIG. 3.

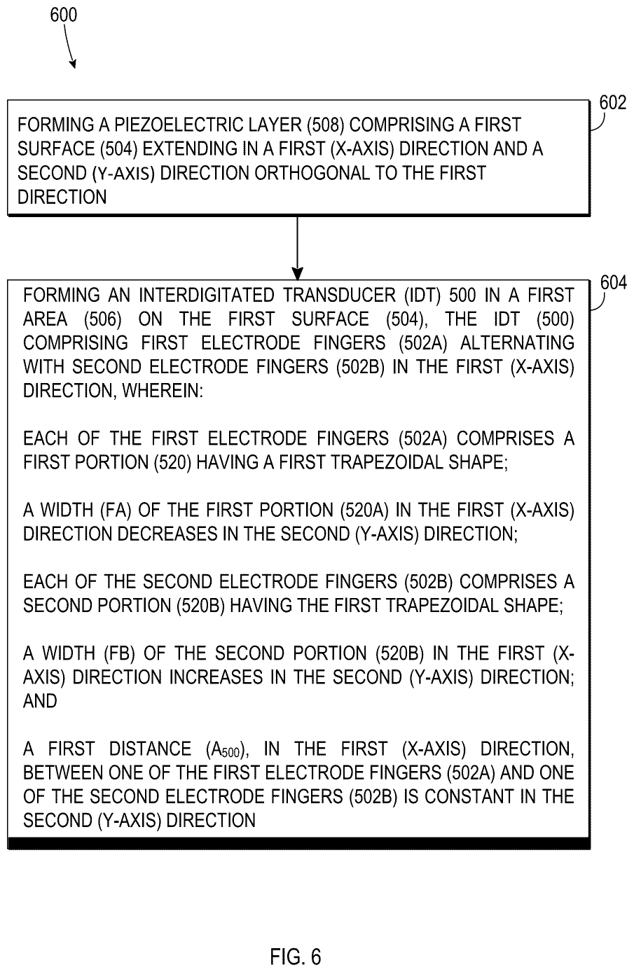

FIG. 6 is a flowchart of a method 600 of making an IDT such as the IDT 500 in FIG. 5A. The method 600 includes forming a piezoelectric layer 508 comprising a first surface 506 extending in a first (X-axis) direction and a second (Y-axis) direction orthogonal to the first direction (block 602); and forming an interdigitated transducer (IDT) 500 in a first area 504 on the first surface 506, the IDT 500 comprising first electrode fingers 502A alternating with second electrode fingers 502B in the first (X-axis) direction, wherein: each of the first electrode fingers 502A comprises a first portion 520 having a first trapezoidal shape; a width FA of the first portion 520A in the first (X-axis) direction decreases in the second (Y-axis) direction; each of the second electrode fingers 502B comprises a second portion 520B having the first trapezoidal shape; a width FB of the second portion 520B in the first (X-axis) direction increases in the second (Y-axis) direction; and a first distance (A₅₀₀), in the first (X-axis) direction, between one of the first electrode fingers 502A and one of the second electrode fingers 502B is constant in the second (Y-axis) direction (block 604).

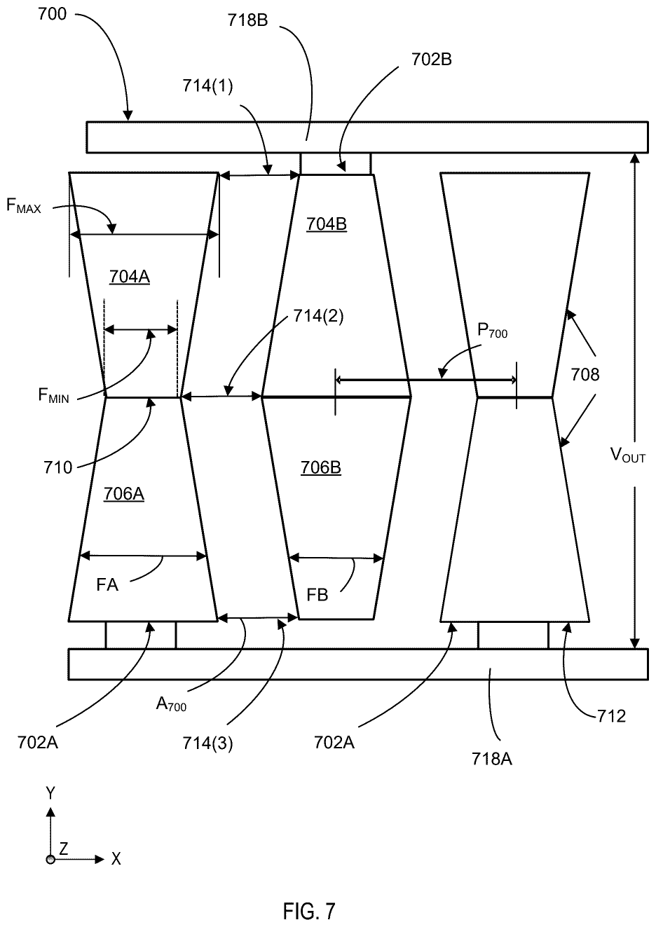

FIG. 7 is a plan view of a second example of an IDT 700 in which first electrode fingers 702A include portions 704A and 706A and second electrode fingers 702B include shaped portions 704B, 706B. Here, all of the portions 704A, 704B, 706A, and 706B have a same trapezoidal shape 708, but the portions 704B and 706B in the second fingers 702B are in an opposite orientation to the portions 704A and 706A in the first type fingers 702A. Thus, the first electrode fingers 702A are also referred to herein as first type fingers 702A, and the second electrode fingers 702B are also referred to herein as second type fingers 702B. The trapezoidal shape 708 includes a first end 710 having a minimum width F_{MIN} and a second end 712 having a maximum width F_{MAX}.

The portions 704A and 706A of the first type finger 702A are coupled at the first ends 710 having the minimum width F_{MIN}. The portions 704B and 706B of the second type fingers 702B are coupled at the second ends 712 having the maximum width F_{MAX}. In this arrangement, the trapezoidal shapes 708 adjacent to each other in the first (X-axis direction) are complementary to each other. Accordingly, the widths FA of the first type fingers 702A increase (e.g., linearly) as the widths FB of the second type fingers 702B decrease (and vice versa) along the second, Y-axis direction to provide a distance A₇₀₀ of separation in the first direction between the first type fingers 702A and the second type fingers 702B that remains constant in the second, Y-axis direction. For example, at each of locations 714(1), 714(2), and 714(3), the first type finger 702A and the second type finger 702B are separated by the distance A₇₀₀. A pitch (center to center distance) P₇₀₀=A₇₀₀+FA+FB of the fingers 702A, 702B remains constant along the lengths of the fingers 702A, 702B.

The first type fingers 702A are coupled to a first interconnect 718A at the second end 712 of portion 706A having the maximum width F_{MAX} and the second type fingers 702B are coupled to a second interconnect 718B at the first end 710 of portion 704B having the minimum width F_{MIN}. An output signal V_{OUT} is a voltage detected between the first interconnect 718A and the second interconnect 718B. As described with reference to the IDTs 400 and 500 in FIGS. 4 and 5A, the complementary trapezoidal shape 708 in the first type fingers 702A and the second type fingers 702B provides a range of metallization ratios in the second, Y-axis direction to spread the effect of a reflected wave (e.g., ripple) over a range of frequencies and/or time to reduce the magnitude of such ripple in the output signal V_{OUT}.

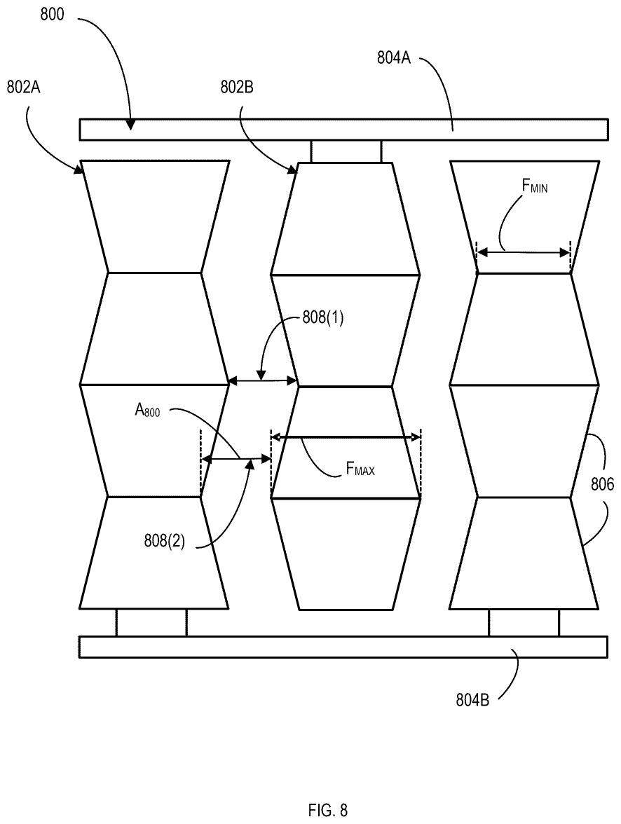

FIG. 8 is a plan view of a third example of an IDT 800 in which first electrode fingers 802A and second electrode fingers 802B each include multiple trapezoidal shaped portions and have constant finger separation to provide a range of frequency response that smooths out the effect of a ripple in an output signal. As in the IDT 700, the first electrode fingers 802A are coupled to a first electrode interconnect 804A and the second electrode fingers 802B are coupled to a second electrode interconnect 804B. The first electrode fingers 802A and the second electrode fingers 802B include a plurality of portions each having a same trapezoidal shape 806, where the portions adjacent to each other in the first, X-axis direction are positioned in a complementary (e.g., opposite) orientation to provide a constant distance A₈₀₀ of separation, such as at locations 808(1) and 808(2). In addition, the respective portions of the fingers 802A, 802B abut each other at ends having a same width (e.g., either the minimum width F_{MIN} or the maximum width F_{MAX}).

As in the examples in FIGS. 4, 5A, and 7, having first electrode fingers 802A and second electrode fingers 802B including trapezoidal shaped portions each with a minimum width F_{MIN} and a maximum width F_{MAX} provides a range of metallization rates in the second, Y-axis direction for a range of frequency responses that smooth out a ripple in an output signal.

Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

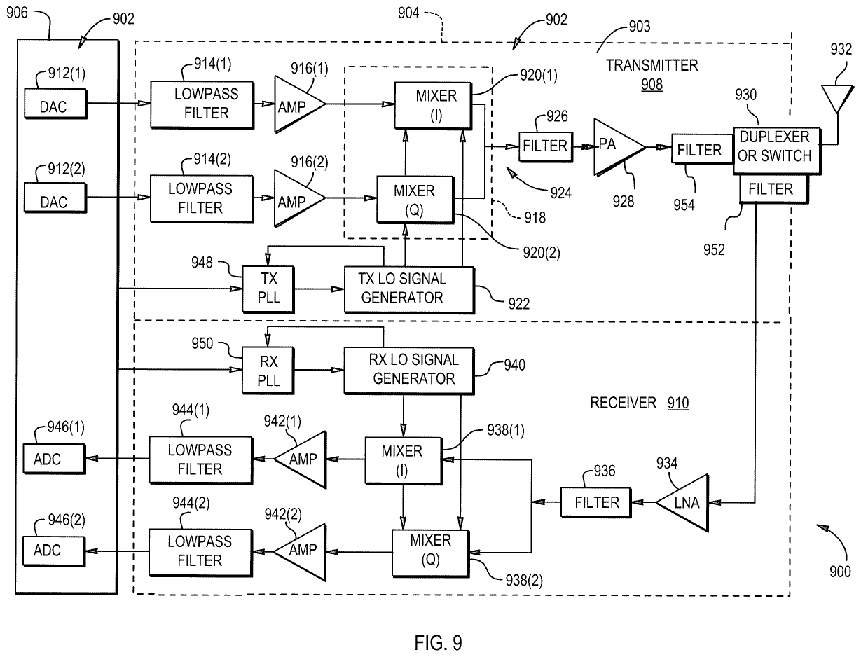

FIG. 9 illustrates an exemplary wireless communications device 900 that includes radio-frequency (RF) components formed from one or more ICs 902, wherein any of the ICs 902 may include microacoustic filters including SAW resonators in which fingers of the IDT include trapezoidal shaped portions and constant finger separation distance to provide a smoothing of a ripple due to reflected waves in the piezoelectric layer, as shown in FIGS. 4, 5A, 7, and 8. The wireless communications device 900 may include or be provided in any of the above-referenced devices, as examples. As shown in FIG. 9, the wireless communications device 900 includes a transceiver 904 and a data processor 906. The data processor 906 may include a memory to store data and program codes. The transceiver 904 includes a transmitter 908 and a receiver 910 that support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 910. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into the I and Q analog output signals (e.g., I and Q output currents) for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals through mixers 920(1), 920(2) from a TX LO signal generator 922 to provide an upconverted signal 924. A filter 926 filters the upconverted signal 924 to remove undesired signals caused by the frequency up-conversion as well as noise in a receive frequency band. A power amplifier (PA) 928 amplifies the upconverted signal 924 from the filter 926 to obtain the desired output power level and provides a transmit RF signal. The transmit RF signal is routed through an output filter 954 and a duplexer or switch 930 and transmitted via an antenna 932.

In the receive path, the antenna 932 receives signals transmitted by base stations and provides a received RF signal, which is routed through the duplexer or switch 930 and an input filter 952 before being provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Down-conversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency up-conversion, while the RX LO signal generator 940 generates the I and Q RX LO signals used for frequency down-conversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

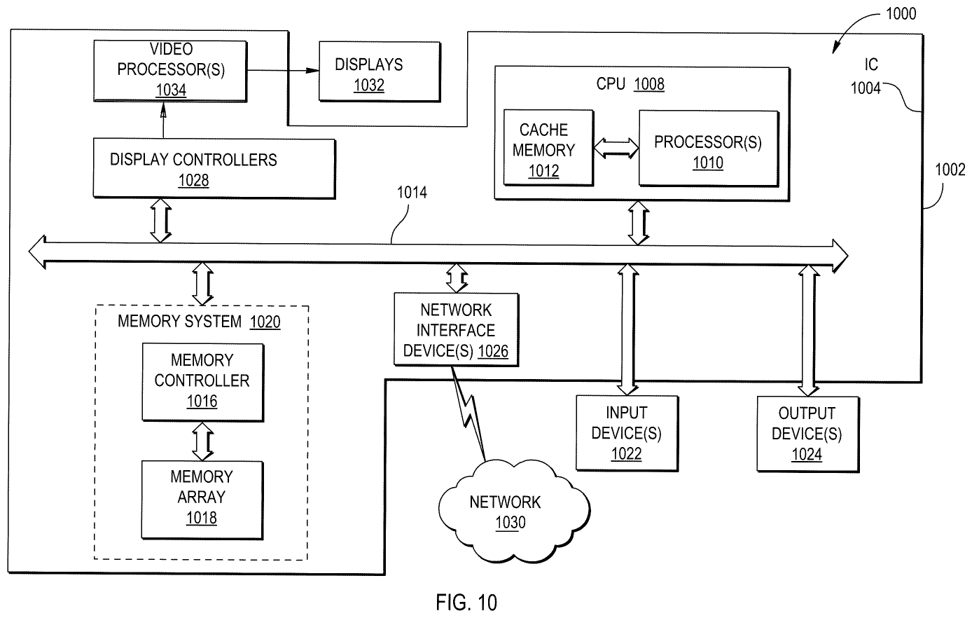

In this regard, FIG. 10 illustrates an example of a processor-based system 1000 that can include microacoustic filters including SAW resonators in which fingers of the IDT include trapezoidal shaped portions and constant finger separation distance to provide a smoothing of a ripple due to reflected waves in the piezoelectric layer, as shown in FIGS. 4, 5A, 7, and 8. The processor-based system 1000 includes a central processing unit (CPU) 1008 that includes one or more processors 1010, which may also be referred to as CPU cores or processor cores. The CPU 1008 may have cache memory 1012 coupled to the CPU 1008 for rapid access to temporarily stored data. The CPU 1008 is coupled to a system bus 1014 and can intercouple master and slave devices included in the processor-based system 1000. As is well known, the CPU 1008 communicates with these other devices by exchanging address, control, and data information over the system bus 1014. For example, the CPU 1008 can communicate bus transaction requests to a memory controller 1016, as an example of a slave device. Although not illustrated in FIG. 10, multiple system buses 1014 could be provided, wherein each system bus 1014 constitutes a different fabric.

Other master and slave devices can be connected to the system bus 1014. As illustrated in FIG. 10, these devices can include a memory system 1020 that includes the memory controller 1016 and a memory array(s) 1018, one or more input devices 1022, one or more output devices 1024, one or more network interface devices 1026, and one or more display controllers 1028, as examples. The input device(s) 1022 can include any type of input device, including, but not limited to, input keys, switches, voice processors, etc. The output device(s) 1024 can include any type of output device, including, but not limited to, audio, video, other visual indicators, etc. The network interface device(s) 1026 can be any device configured to allow an exchange of data to and from a network 1030. The network 1030 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1026 can be configured to support any type of communications protocol desired.

The CPU 1008 may also be configured to access the display controller(s) 1028 over the system bus 1014 to control information sent to one or more displays 1032. The display controller(s) 1028 sends information to the display(s) 1032 to be displayed via one or more video processor(s) 1034, which processes the information to be displayed into a format suitable for the display(s) 1032. The display(s) 1032 can include any type of display, including, but not limited to, a cathode ray tube (CRT), a liquid crystal display (LCD), a plasma display, a light emitting diode (LED) display, etc.

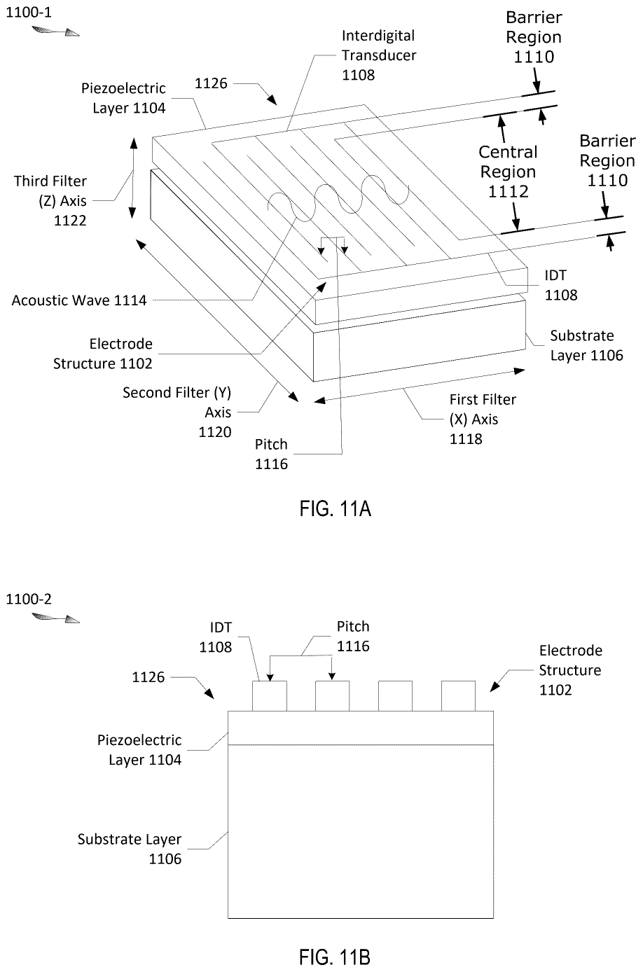

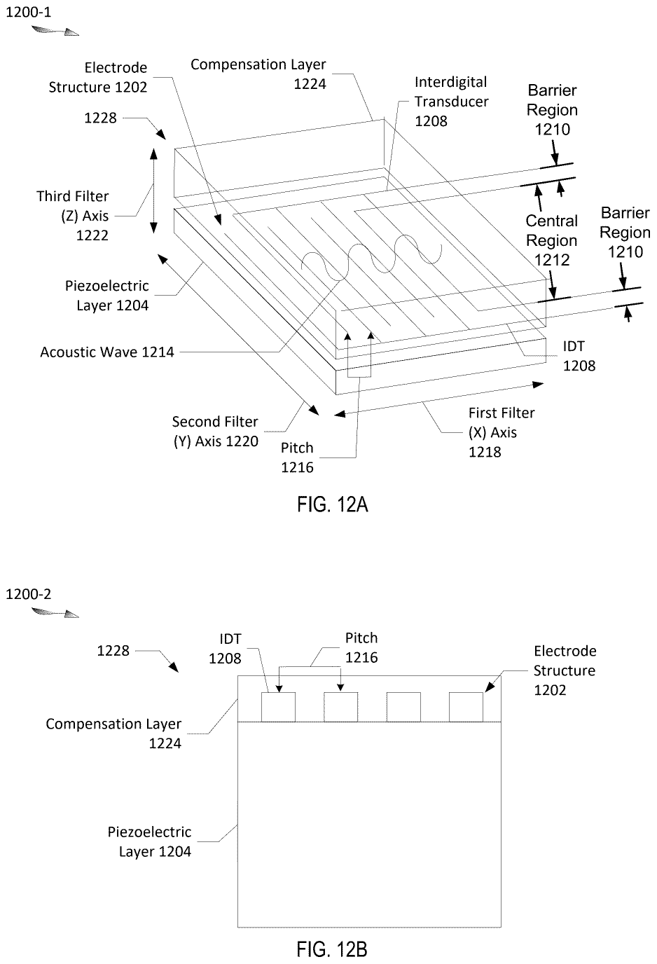

Further examples and details of SAW resonators in which IDT fingers including trapezoidal shapes and constant finger separation distance may be employed are described with reference to FIGS. 11A, 11B, 12A, and 12B. FIGS. 11A and 11B illustrate an example implementation of a thin-film (TF) SAW (TF-SAW) filter 1126. A three-dimensional perspective view 1100-1 of the TF-SAW filter 1126 is shown in FIG. 11A, and a two-dimensional (2D) cross sectional view 1100-2 of the TF-SAW filter 1126 is shown in FIG. 11B. In some cases, the TF-SAW filter 1126 can correspond to the TF-SAW filter 126 of FIGS. 4, 5A, 7, and 8.

The TF-SAW filter 1126 includes at least one electrode structure 1102. The TF-SAW filter 1126 also includes at least one piezoelectric layer 1104 (e.g., piezoelectric material) and at least one substrate layer 1106. The electrode structure 1102 is implemented using conductive material, such as metal, and can include one or more layers. The one or more layers can include one or more metal layers and can optionally include one or more adhesion layers. As an example, the metal layers can be composed of aluminum (Al), copper (Cu), silver (Ag), gold (Au), tungsten (W), or some combination or doped version thereof. The adhesion layers can be composed of chromium (Cr), titanium (Ti), molybdenum (Mo), or some combination thereof.

The electrode structure 1102 can include one or more interdigitated transducers (IDTs) 1108, which may be any of the IDTS 400, 500, 700, and 800 in FIGS. 4, 5A, 7, and 8. The IDT 1108 converts an electrical signal into an acoustic wave and converts the acoustic wave into a filtered electrical signal. Although not explicitly shown, the electrode structure 1102 can also include two or more reflectors. In an example implementation, the IDT 1108 is arranged between two reflectors (not shown), which reflect the acoustic wave back towards the IDT 1108.

The piezoelectric layer 1104 can be implemented using a variety of different materials that exhibit piezoelectric properties (e.g., can transfer mechanical energy into electrical energy or electrical energy into mechanical energy). Example types of material include lithium niobate (LN) or compounds thereof, lithium tantalate (LT) or compounds thereof, or quartz. In general, the material that forms the piezoelectric layer 1104 has a crystalline structure. This crystalline structure is defined by an ordered arrangement of particles (e.g., atoms, ions, or molecules).

The substrate layer 1106 includes one or more sublayers that can support passivation, temperature compensation, power handling, mode suppression, and so forth. As an example, the substrate layer 1106 can include at least one compensation layer (e.g., temperature compensation layer), at least one charge-trapping layer, at least one support layer, or some combination thereof. These sublayers can be considered part of the substrate layer 1106 or their own separate layers. Example types of material that can form one or more sublayers within the substrate layer 1106 include silicon dioxide (SiO₂)—such as for the (e.g., temperature) compensation layer, polysilicon (poly-Si) (e.g., polycrystalline silicon or multicrystalline silicon such as for the trap rich or charge-trapping layer), amorphous silicon, silicon nitride (SiN), silicon oxynitride (SiON), aluminums nitride (AlN), non-conducting material (e.g., silicon (Si), doped silicon, sapphire, silicon carbide (SiC), fused silica, glass, diamond (such as for a base substrate layer), or some combination thereof.

In the three-dimensional perspective view 1100-1, the IDT 1108 is shown to have two comb-shaped electrode structures with fingers (e.g., electrode fingers) extending from two busbars (e.g., conductive segments or rails) towards each other in an interleaved fashion (e.g., interleaved electrode fingers). The fingers are arranged in an interlocking or interleaved manner in between the two busbars of the IDT 1108 (e.g., arranged in an interdigitated manner). In other words, the fingers connected to a first busbar extend towards a second busbar but do not connect to the second busbar. As such, there is a barrier region 1110 between the ends of these fingers and the second busbar. Likewise, fingers connected to the second busbar extend towards the first busbar but do not connect to the first busbar. There is therefore a barrier region 1110 between the ends of these fingers and the first busbar.

In the direction along the busbars, there is an overlap region including a central region 1112 where a portion of one finger overlaps with a portion of an adjacent finger. This central region 1112, including the overlap, may be referred to as the aperture, track, or active region where electric fields are produced between fingers to cause an acoustic wave 1114 to form at least in this region of the piezoelectric layer 1104.

A physical periodicity of the fingers is referred to as a pitch 1116 of the IDT 1108. The pitch 1116 may be indicated in various ways. For example, in certain aspects, the pitch 1116 may correspond to a magnitude of a distance between consecutive fingers of the IDT 1108 in the central region 1112. This distance may be defined, for example, as the distance between center points of each of the fingers. The distance may be generally measured between a right (or left) edge of one finger and the right (or left) edge of an adjacent finger when the fingers have uniform widths. In certain aspects, an average of the distances between adjacent fingers of the IDT 1108 may be used for the pitch 1116. The frequency at which the piezoelectric layer 1104 vibrates is a main-resonance frequency of the electrode structure 1102. The frequency is determined at least in part by the pitch 1116 of the IDT 1108 and other properties of the TF-SAW filter 1126.

Although not shown, each reflector within the electrode structure 1102 can have two busbars and a grating structure of conductive fingers that each connect to both busbars. In some implementations, the pitch of the reflector can be similar to or the same as the pitch 1116 of the IDT 1108 to reflect the acoustic wave 1114 in the resonant frequency range.

In some cases, although not illustrated as such in FIGS. 11A and 11B, a resonator can include multiple components (e.g., in addition to an IDT 1108 with multiple fingers). For example, a resonator can include an IDT 1108 and at least one reflector (not shown), such as a pair of reflectors. In one illustrative example, the IDT 1108 can be coupled together with the IDT 1108 between a first reflector and a second reflector (e.g., coupled together as follows: Reflector1+IDT+Reflector2) to form a resonator. In some cases, multiple resonators can be connected together (e.g., in a ladder network, a double-mode SAW (DMS) filter, or otherwise) to form a filter.

It should be appreciated that while a certain number of fingers are illustrated in FIGS. 4, 5A, 7, 8, 11A, 11B, 12A, and 12B, the number of actual fingers and lengths and width of the fingers and busbars may be different in an actual implementation. Such parameters depend on the particular application and desired filter characteristics. In addition, the TF-SAW filter 1126 can include multiple interconnected electrode structures each including multiple IDTs 1108 to achieve a desired passband (e.g., multiple interconnected resonators or IDTs 1108 in series or parallel connections to form a desired filter transfer function).

In the three-dimensional perspective view 1100-1, the TF-SAW filter 1126 is defined by an x-axis 1118, a y-axis 1120, and a z-axis 1122. The x-axis 1118 and the y-axis 1120 are parallel to a planar surface of the piezoelectric layer 1104, and the y-axis 1120 is perpendicular to the x-axis 1118. The z-axis 1122 is normal (e.g., perpendicular) to the planar surface of the piezoelectric layer 1104. The busbars of the IDT 1108 are oriented to be parallel to the x-axis 1118. The fingers of the IDT 1108 are oriented to be parallel to the y-axis 1120. Also, an orientation of the piezoelectric layer 1104 causes an acoustic wave 1114 to mainly form in a direction of the x-axis 1118. As such, the acoustic wave 1114 forms in a direction that is substantially perpendicular to the direction of the fingers of the IDT 1108.

FIG. 12A 12B illustrate an example implementation of a temperature compensated (TC) SAW (TC-SAW) filter 1228. A three-dimensional perspective view 1200-1 of the TC-SAW filter 1228 is shown in FIG. 12A, and a two-dimensional (2D) cross sectional view 1200-2 of the TC-SAW filter 1228 is shown in FIG. 12B.

The TC-SAW filter 1228 includes at least one electrode structure 1202, at least one piezoelectric layer 1204, and at least one optional compensation layer 1224. In some implementations, the compensation layer 1224 can provide temperature compensation to enable the TC-SAW filter 1228 to achieve a target temperature coefficient of frequency. In example implementations, the compensation layer 1224 can be implemented using at least one silicon dioxide layer. In some implementations, a SAW filter may be formed without the inclusion of the optional compensation layer 1224.

In the depicted configuration shown in the cross sectional view 1200-2, the electrode structure 1202 is disposed between the piezoelectric layer 1204 and the compensation layer 1224. The piezoelectric layer 1204 can form a substrate of the TC-SAW filter 1228.

The electrode structure 1202 of the TC-SAW filter 1228 can be similar to the electrode structure 1102 described above with respect to the TF-SAW filter 1126 of FIG. 11A. Likewise, the piezoelectric layer 1204 of the TC-SAW filter 1228 can be similar to the piezoelectric layer 1104 described above with respect to the TF-SAW filter 1126 of FIG. 11A. In some implementations, the piezoelectric layer 1204 of the TC-SAW filter 1228 can be thicker than the piezoelectric layer 1104 of the TF-SAW filter 1126 of FIGS. 11A and 11B.

In the three-dimensional perspective view 1200-1, the TC-SAW filter 1228 is defined by an x-axis 1218, a y-axis 1220, and a z-axis 1222. The x-axis 1218 and the y-axis 1220 are parallel to a planar surface of the piezoelectric layer 1204, and the y-axis 1220 is perpendicular to the x-axis 1218. The z-axis 1222 is normal (e.g., perpendicular) to the planar surface of the piezoelectric layer 1204. The busbars of the IDT 1208 are oriented to be parallel to the x-axis 1218. The fingers of the IDT 1208 are oriented to be parallel to the y-axis 1220. The physical periodicity of the fingers of the IDT 1208 is indicated by a pitch 1216. The IDT 1208 may be any of the IDTs 400, 500, 700, 800. Also, an orientation of the piezoelectric layer 1204 causes an acoustic wave 1214 to mainly form in a direction of the x-axis 1218. As such, the acoustic wave 1214 forms in a direction that is substantially perpendicular to the direction of the fingers of the IDT 1208. Similar to the TF-SAW filter 1126 of FIGS. 11A and 11B, the TC-SAW filter 1228 of FIGS. 12A and 12B can also include a barrier region 1210 and a central region 1212.

In some cases, the SAW filter can correspond to the TF-SAW filter 1126 of FIG. 11A or the TC-SAW filter 1228 of FIG. 12A. For the purposes of illustration, operation of the TC-SAW filter 1228 of FIGS. 12A and 12B will be described below. The TF-SAW filter 1126 can have similar operations to the TC-SAW filter 1228.

Referring to FIG. 12A, the electrode structure 1202 excites an acoustic wave 1214 on the piezoelectric layer 1204 using the inverse piezoelectric effect. For example, the IDT 1208 in the electrode structure 1202 generates an alternating electric field based on the accepted RF signal. The piezoelectric layer 1204 enables the acoustic wave 1214 to be formed in response to the alternating electric field generated by the IDT 1208. In other words, the piezoelectric layer 1204 causes, at least partially, the acoustic wave 1214 to form responsive to electrical stimulation by one or more IDTs 1208.

The acoustic wave 1214 propagates across the piezoelectric layer 1204 and interacts with the IDT 1208 or another IDT within the electrode structure 1202 (not shown). The acoustic wave 1214 that propagates can be a standing wave. In some implementations, two reflectors within the electrode structure 1202 cause the acoustic wave 1214 to be formed as a standing wave across a portion of the piezoelectric layer 1204. In other implementations, the acoustic wave 1214 propagates across the piezoelectric layer 1204 from the IDT 1208 to another IDT (not shown).

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A surface acoustic wave (SAW) resonator comprising:
   a piezoelectric layer comprising a first surface having a first area extending in a first direction and a second direction orthogonal to the first direction; and
   an interdigitated transducer (IDT) structure disposed on or above the first surface in the first area, the IDT structure comprising first electrode fingers alternating with second electrode fingers in the first direction,
   wherein:
      each of the first electrode fingers comprises a first portion having a trapezoidal shape;
      a width of the first portion in the first direction decreases in the second direction;
      each of the second electrode fingers comprises a second portion having a trapezoidal shape;
      a width of the second portion in the first direction increases in the second direction; and
      a first distance, in the first direction, between a first electrode finger of the first electrode fingers and a second electrode finger of the second electrode fingers is constant in the second direction.
2. The SAW resonator of clause 1, the IDT structure further comprising:
   a first interconnect extending in the first direction on a first side of the first area and coupled to a first end of each of the first electrode fingers; and
   a second interconnect extending in the first direction on a second side of the first area and coupled to a first end of each of the second electrode fingers.
3. The SAW resonator of clause 2, wherein:
   a second end of each of the first electrode fingers opposite to the first end comprises a first linear edge extending in the first direction; and
   a second end of each of the second electrode fingers opposite to the first end comprises a second linear edge extending in the first direction.
4. The SAW resonator of clause 3, wherein:
   a width in the first direction of the first end of each of the first electrode fingers is a minimum width of the first portion in the first direction; and
   a width in the first direction of the second end of each of the second electrode fingers is a maximum width of the first portion in the first direction.
5. The SAW resonator of clause 3 or clause 4, wherein:
   the first end of each of the first electrode fingers and the second end of each of the second electrode fingers are separated by a second distance in the first direction; and
   the second end of each of the first electrode fingers and the first end of each of the second electrode fingers are separated by the second distance in the first direction.
6. The SAW resonator of clause 4 or clause 5, wherein the minimum width of the first portion is in a range of eighty-nine percent (89%) to ninety-five percent (95%) of the maximum width in the first direction of the first portion.
7. The SAW resonator of any of clause 3 to clause 6, wherein:
   the first portion in each of the first electrode fingers extends in the second direction from the first end to the second end of the first electrode fingers; and
   the second portion in each of the second electrode fingers extends in the second direction from the first end to the second end of the second electrode fingers.
8. The SAW resonator of any of clause 1 to clause 7, wherein a length in the second direction of each of the first electrode fingers is greater than twice a maximum width in the first direction of the first portion.
9. The SAW resonator of any of clause 1 to clause 8, wherein each of the first electrode fingers is symmetric to a center axis extending in the second direction.
10. The SAW resonator of any of clause 1 to clause 9, wherein the first distance in the first direction between a first electrode finger of the first electrode fingers and a second electrode finger of the second electrode fingers is in a range of nineteen percent (19%) to two-hundred fifty percent (250%) of an average width in the first direction of the first portion of each of the first electrode fingers.
11. The SAW resonator of any of clause 1 to clause 10, wherein:
   each of the first electrode fingers comprises a third portion having the trapezoidal shape; and
   each of the second electrode fingers comprises a fourth portion having the trapezoidal shape.
12. The SAW resonator of clause 11, wherein:
   a width of the third portion in the first direction increases in the second direction; and
   a width of the fourth portion in the first direction decreases in the second direction.
13. The SAW resonator of any of clause 1 to clause 12, wherein:
   the IDT structure extends over a surface area of the piezoelectric layer;
   a ratio of a total area of the first electrode fingers and the second electrode fingers in the first direction and the second direction to the surface area of the piezoelectric layer is in a range of 30 percent (30%) to eighty percent (80%).
14. The SAW resonator of any of clause 11 to clause 13, wherein:
   each of the first electrode fingers comprises a fifth portion having the trapezoidal shape; and
   each of the second electrode fingers comprises a sixth portion having the trapezoidal shape.
15. The SAW resonator of any of clause 1 to clause 14 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
16. A microacoustic filter comprising:
   a plurality of surface acoustic wave (SAW) resonators each comprising:
      a piezoelectric layer comprising a first surface having a first area extending in a first direction and a second direction orthogonal to the first direction; and
      an interdigitated transducer (IDT) structure on the first surface in the first area, the IDT structure comprising first electrode fingers alternating with second electrode fingers in the first direction,
      wherein:
         each of the first electrode fingers comprises a first portion having a first trapezoidal shape;
         a width of the first portion in the first direction decreases in the second direction;
         each of the second electrode fingers comprises a second portion having the first trapezoidal shape;
         a width of the second portion in the first direction increases in the second direction; and
         a first distance, in the first direction, between a first electrode finger of the first electrode fingers and a second electrode finger of the second electrode fingers is constant in the second direction.
17. A method of manufacturing a surface acoustic wave (SAW) resonator, the method comprising:
   forming a piezoelectric layer comprising a first surface having a first area extending in a first direction and a second direction orthogonal to the first direction; and
   forming an interdigitated transducer (IDT) structure on the first surface in the first area, the IDT structure comprising first electrode fingers alternating with second electrode fingers in the first direction,
   wherein:
      each of the first electrode fingers comprises a first portion having a first trapezoidal shape;
      a width of the first portion in the first direction decreases in the second direction;
      each of the second electrode fingers comprises a second portion having the first trapezoidal shape;
      a width of the second portion in the first direction increases in the second direction; and
      a first distance, in the first direction, between a first electrode finger of the first electrode fingers and a second electrode finger of the second electrode fingers is constant in the second direction.
18. The method of clause 17, wherein forming the IDT structure further comprises:
   forming a first interconnect extending in the first direction on a first side of the first area and coupled to a first end of each of the first electrode fingers; and
   forming a second interconnect extending in the first direction on a second side of the first area and coupled to a first end of each of the second electrode fingers,
   wherein:
      a second end of each of the first electrode fingers opposite to the first end comprises a first linear edge extending in the first direction; and
      a second end of each of the second electrode fingers opposite to the first end comprises a second linear edge extending in the first direction.
19. The method of clause 17 or clause 18, wherein:
   the first end of each of the first electrode fingers and the second end of each of the second electrode fingers is separated by a second distance in the first direction; and
   the second end of each of the first electrode fingers and the first end of each of the second electrode fingers is separated by the second distance in the first direction.
20. The method of any of clause 17 to clause 19, wherein a minimum width of the first portion is in a range of eighty-nine percent (89%) to ninety-five percent (95%) of a maximum width in the first direction of the first portion.

What is claimed is:

1. A surface acoustic wave (SAW) resonator comprising:
a piezoelectric layer comprising a first surface having a first area extending in a first direction and a second direction orthogonal to the first direction; and
an interdigitated transducer (IDT) structure disposed on or above the first surface in the first area, the IDT structure comprising first electrode fingers alternating with second electrode fingers in the first direction,
wherein:
each of the first electrode fingers comprises a first portion having a trapezoidal shape;
a width of the first portion in the first direction decreases in the second direction;
each of the second electrode fingers comprises a second portion having a trapezoidal shape;
a width of the second portion in the first direction increases in the second direction; and
a first distance, in the first direction, between a first electrode finger of the first electrode fingers and a second electrode finger of the second electrode fingers is constant in the second direction.

2. The SAW resonator of claim 1, the IDT structure further comprising:
a first interconnect extending in the first direction on a first side of the first area and coupled to a first end of each of the first electrode fingers; and
a second interconnect extending in the first direction on a second side of the first area and coupled to a first end of each of the second electrode fingers.

3. The SAW resonator of claim 2, wherein:
a second end of each of the first electrode fingers opposite to the first end comprises a first linear edge extending in the first direction; and
a second end of each of the second electrode fingers opposite to the first end comprises a second linear edge extending in the first direction.

4. The SAW resonator of claim 3, wherein:
a width in the first direction of the first end of each of the first electrode fingers is a minimum width of the first portion in the first direction; and
a width in the first direction of the second end of each of the second electrode fingers is a maximum width of the first portion in the first direction.

5. The SAW resonator of claim 3, wherein:
the first end of each of the first electrode fingers and the second end of each of the second electrode fingers are separated by a second distance in the first direction; and
the second end of each of the first electrode fingers and the first end of each of the second electrode fingers are separated by the second distance in the first direction.

6. The SAW resonator of claim 4, wherein the minimum width of the first portion is in a range of eighty-nine percent (89%) to ninety-five percent (95%) of the maximum width in the first direction of the first portion.

7. The SAW resonator of claim 3, wherein:
the first portion in each of the first electrode fingers extends in the second direction from the first end to the second end of the first electrode fingers; and
the second portion in each of the second electrode fingers extends in the second direction from the first end to the second end of the second electrode fingers.

8. The SAW resonator of claim 1, wherein a length in the second direction of each of the first electrode fingers is greater than twice a maximum width in the first direction of the first portion.

9. The SAW resonator of claim 1, wherein each of the first electrode fingers is symmetric to a center axis extending in the second direction.

10. The SAW resonator of claim 1, wherein the first distance in the first direction between a first electrode finger of the first electrode fingers and a second electrode finger of the second electrode fingers is in a range of nineteen percent (19%) to two-hundred fifty percent (250%) of an average width in the first direction of the first portion of each of the first electrode fingers.

11. The SAW resonator of claim 1, wherein:
each of the first electrode fingers comprises a third portion having the trapezoidal shape; and
each of the second electrode fingers comprises a fourth portion having the trapezoidal shape.

12. The SAW resonator of claim 11, wherein:
a width of the third portion in the first direction increases in the second direction; and
a width of the fourth portion in the first direction decreases in the second direction.

13. The SAW resonator of claim 1, wherein:
the IDT structure extends over a surface area of the piezoelectric layer;
a ratio of a total area of the first electrode fingers and the second electrode fingers in the first direction and the second directions to the surface area of the piezoelectric layer is in a range of 30 percent (30%) to eighty percent (80%).

14. The SAW resonator of claim 11, wherein:
each of the first electrode fingers comprises a fifth portion having the first trapezoidal shape; and
each of the second electrode fingers comprises a sixth portion having the first trapezoidal shape.

15. The SAW resonator of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

16. A microacoustic filter comprising:
a plurality of surface acoustic wave (SAW) resonators each comprising:
a piezoelectric layer comprising a first surface having a first area extending in a first direction and a second direction orthogonal to the first direction; and
an interdigitated transducer (IDT) structure on the first surface in the first area, the IDT structure comprising first electrode fingers alternating with second electrode fingers in the first direction,
wherein:
each of the first electrode fingers comprises a first portion having a first trapezoidal shape;
a width of the first portion in the first direction decreases in the second direction;
each of the second electrode fingers comprises a second portion having the first trapezoidal shape;
a width of the second portion in the first direction increases in the second direction; and
a first distance, in the first direction, between a first electrode finger of the first electrode fingers and a second electrode finger of the second electrode fingers is constant in the second direction.

17. A method of manufacturing a surface acoustic wave (SAW) resonator, the method comprising:
forming a piezoelectric layer comprising a first surface having a first area extending in a first direction and a second direction orthogonal to the first direction; and
forming an interdigitated transducer (IDT) structure on the first surface in the first area, the IDT structure comprising first electrode fingers alternating with second electrode fingers in the first direction,
wherein:
each of the first electrode fingers comprises a first portion having a first trapezoidal shape;
a width of the first portion in the first direction decreases in the second direction;
each of the second electrode fingers comprises a second portion having the first trapezoidal shape;
a width of the second portion in the first direction increases in the second direction; and
a first distance, in the first direction, between a first electrode finger of the first electrode fingers and a second electrode finger of the second electrode fingers is constant in the second direction.

18. The method of claim 17, wherein forming the IDT structure further comprises:
forming a first interconnect extending in the first direction on a first side of the first area and coupled to a first end of each of the first electrode fingers; and
forming a second interconnect extending in the first direction on a second side of the first area and coupled to a first end of each of the second electrode fingers,
wherein:
a second end of each of the first electrode fingers opposite to the first end comprises a first linear edge extending in the first direction; and
a second end of each of the second electrode fingers opposite to the first end comprises a second linear edge extending in the first direction.

19. The method of claim 18, wherein:
the first end of each of the first electrode fingers and the second end of each of the second electrode fingers is separated by a second distance in the first direction; and
the second end of each of the first electrode fingers and the first end of each of the second electrode fingers is separated by the second distance in the first direction.

20. The method of claim 19, wherein a minimum width of the first portion is in a range of eighty-nine percent (89%) to ninety-five percent (95%) of a maximum width in the first direction of the first portion.
